(19) United States
(12) Patent Application Publication
(10) Pub. No.: US 2025/0237007 A1
(43) Pub. Date: Jul. 24, 2025

(54) Garment Steamer and Operation Control Method Thereof

(71) Applicant: Shenzhen Tengben Technology Co., Ltd., Shenzhen Guangdong (CN)

(72) Inventors: Chengzhu Ren, Shenzhen (CN); Shuiyong Yu, Shenzhen (CN); Zhongming Yu, Shenzhen (CN)

(21) Appl. No.: 18/942,747

(22) Filed: Nov. 10, 2024

(30) Foreign Application Priority Data
Jan. 19, 2024 (CN) 202420144085.X

(51) Int. Cl. D06F 75/26; D06F 75/18; D06F 75/28; D06F 75/34; D06F 75/36; H03K 17/687

(52) U.S. Cl. CPC D06F 75/26; D06F 75/18; D06F 75/28; D06F 75/34; D06F 75/36; H03K 17/6871

(57) ABSTRACT

A garment steamer includes a power connector, a heating element, a temperature controller, a pump, a transistor drive circuit and a switch, wherein the power connector is used to be electrically connected to a power source, the switch is used to control the start and stop of the garment steamer, the heating element is connected in parallel with the pump, the temperature controller is connected in parallel with the transistor drive circuit, the temperature controller is used to sense the temperature of the heating element, and to turn on or off according to the sensed temperature.

### CROSS REFERENCE OF RELATED APPLICATION

This application is a non-provisional application that claims priority under 35 U.S.C. § 119 to China application number CN202420144085.X, filing date Jan. 19, 2024, wherein the entire content of which is expressly incorporated herein by reference.

### BACKGROUND OF THE PRESENT INVENTION

### Field of Invention

The present invention relates to steamer device, and more particularly to a garment steamer for intelligently controlling the heating and water supply operations.

### Description of Related Arts

A conventional garment steamer is controlled by switches, and users select heating or water supply through the switches, so that it is not smart enough and even have defects such as water spraying. In order to improve the level of intelligence, high-end chips such as processors and microcontrollers are needed, which will increase the overall cost of the garment steamer.

More specifically, a conventional garment steamer can be equipped with a control button featuring three levels and two indicator lights. The first level is designated to stop the operation. When the button is switched to the second level, a red indicator light illuminates, signaling that the heating element is activated, and the machine enters a preheating phase. Once the green light turns on, the preheating process is complete, indicating that the user can then push the button to the third level to initiate the pump and generate steam.

However, there is a significant drawback to this design. If the user applies too much force while adjusting the control, they might accidentally skip the second level and push the button directly to the third level. This premature activation causes the pump to start before the heating element has fully preheated, leading to the release of water instead of steam. In other words, the user may unintentionally skip the preheating stage, the pump activates prematurely, releasing water, which can result in poor performance or even damage certain fabrics.

The three-level design of the control button can be counterintuitive, especially for inexperienced users. The requirement to precisely navigate between levels adds complexity, making the device less user-friendly. This may cause frustration, particularly if the user is unaware of why water is being released instead of steam.

In continuous operation of the conventional garment steamer, the heating element of the garment steamer is regulated within a specific temperature range. When the element reaches a set high temperature, it automatically stops heating. Once the temperature drops to a predetermined lower threshold, the heating element reactivates. During this normal cycle, the conventional garment steamer uses the red indicator light to signal that the heating element has resumed heating, which remains on until the temperature reaches the upper limit and the green light signals that the steamer is ready to produce steam again. However, the alternating flashing of the red and green lights during this process can confuse the user.

The frequent switching between red and green lights can give the impression that something is malfunctioning or that the steamer requires user intervention, even though it is simply following its normal operating cycle. This can be particularly confusing for new or inexperienced users, leading them to question whether the device is functioning properly.

When the red light turns on during steaming, users may assume that the steamer is no longer producing steam, even though it is heating up again within the normal cycle. This could lead to unnecessary pauses in use or hesitation, negatively affecting the user experience. Constantly flashing lights during normal operation may lead to distraction or annoyance, especially during longer steaming sessions. The visual signals meant to guide the user could become overwhelming, diminishing the intuitive operation of the device.

### SUMMARY OF THE PRESENT INVENTION

According to an aspect, the present application provides a garment steamer, comprising a power connector, a heating element, a temperature controller, a pump, a transistor drive circuit and a switch, wherein the power connector is used to be electrically connected to a power source, the switch is used to control the start and stop of the garment steamer, the heating element is connected in parallel with the pump, the temperature controller is connected in parallel with the transistor drive circuit, the temperature controller is used to sense the temperature of the heating element, and to turn on or off according to the sensed temperature.

When the power connector is electrically connected to the power source, the power source, the pump, the transistor drive circuit and the switch are connected in series to form a first circuit loop, the power source, the heating element, the transistor drive circuit and the switch are connected in series to form a second circuit loop, and the power source, the heating element, the temperature controller and the switch are connected in series to form a third circuit loop.

The transistor drive circuit is used to turn on the first circuit loop when the temperature controller is turned off, and to turn off the first circuit loop when the temperature controller is turned on.

The technical solution described in the present application has the following beneficial effects: the present application controls the start and stop of the garment steamer through a switch, and selects heating of the heating element or water supply by a pump through the cooperation of the temperature controller and the transistor drive circuit, thereby improving the intelligence of the garment steamer. In addition, the transistor drive circuit in the garment steamer uses transistors that are much cheaper than high-end chips such as processors and microcontrollers, thereby reducing the cost of a garment steamer that is controlled based on the cooperation of a temperature controller and a transistor drive circuit.

### BRIEF DESCRIPTION OF THE DRAWINGS

FIG. 1 is a circuit diagram of a garment steamer according to some embodiments of the present application;

FIG. 2 is a schematic diagram of the structure of the garment steamer in the embodiment shown in FIG. 1 according to some embodiments;

FIG. 3 is a schematic diagram of the structure of the garment steamer in the embodiment shown in FIG. 1 according to some embodiments;

FIG. 4 is a schematic diagram of the structure of a transistor drive circuit in the embodiment shown in FIG. 1 according to some embodiments;

FIG. 5 is a schematic diagram of the structure of the transistor drive circuit in the embodiment shown in FIG. 4 according to some embodiments;

FIG. 6 is a schematic diagram of the structure of the transistor drive circuit in the embodiment shown in FIG. 5;

FIG. 7 is a circuit diagram of a driving power source according to the embodiment shown in FIG. 4;

FIG. 8 is a circuit diagram of the driving power source in the embodiment shown in FIG. 4;

FIG. 9 is a schematic diagram of the structure of an alternative garment steamer according to some embodiments;

FIG. 10 is a perspective view of the garment steamer according to some embodiments;

FIG. 11 is an exploded view of the garment steamer according to some embodiments.

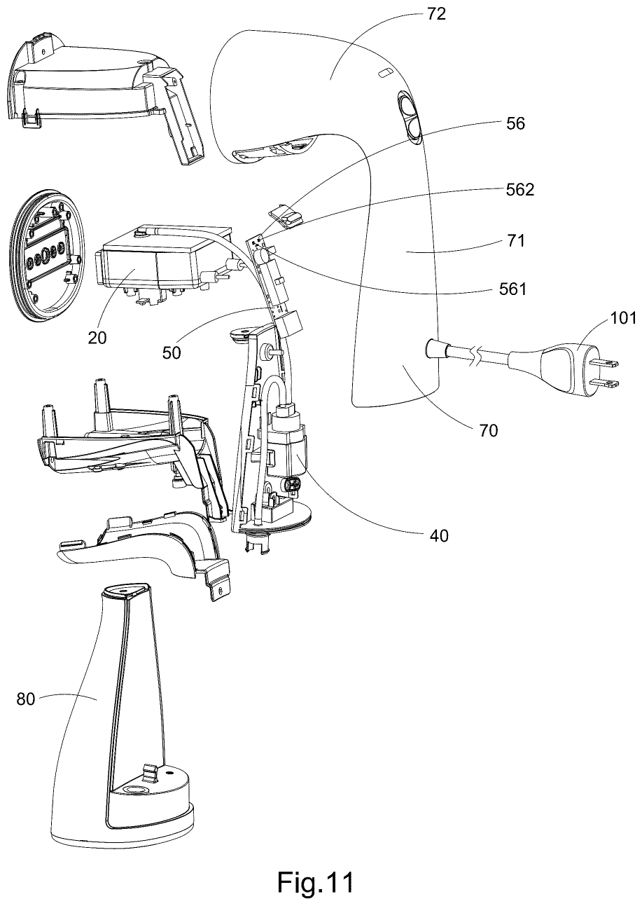

### DETAILED DESCRIPTION OF THE PREFERRED EMBODIMENT

The following description is disclosed to enable any person skilled in the art to make and use the present invention. Preferred embodiments are provided in the following description only as examples and modifications will be apparent to those skilled in the art. The general principles defined in the following description would be applied to other embodiments, alternatives, modifications, equivalents, and applications without departing from the spirit and scope of the present invention.

The technical solutions in the embodiments of the present application will be described clearly and completely below in conjunction with the drawings in the embodiments of the present application. Obviously, the described embodiments are only part of the embodiments of the present application, not all of the embodiments. Based on the embodiments in the present application, all other embodiments obtained by ordinary technicians in this field without creative work are within the scope of protection of this application.

Reference to “embodiments” herein means that a particular feature, structure, or characteristic described in conjunction with the embodiments can be included in at least one embodiment of the present application. The appearance of the phrase in various locations in the specification does not necessarily refer to the same embodiment, nor is it an independent or alternative embodiment that is mutually exclusive with other embodiments. It is explicitly and implicitly understood by those skilled in the art that the embodiments described herein can be combined with other embodiments.

The present application describes a garment steamer. The garment steamer reduces the overall cost by simplifying the design of the internal circuit. In addition, the garment steamer can be convenient for users and improve the user experience during use.

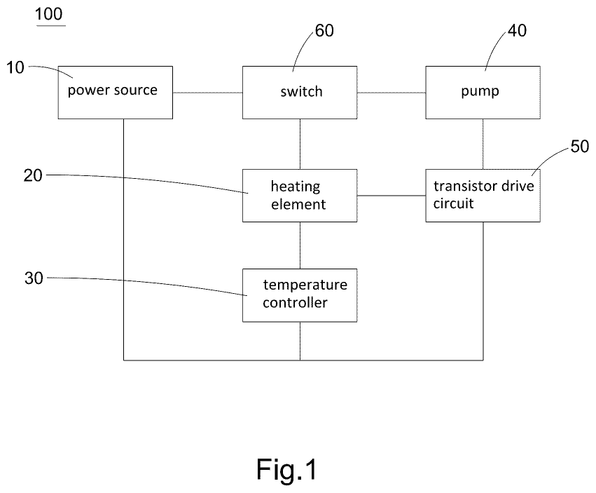

Please refer to FIG. 1, which is a circuit diagram of a garment steamer 100 according to some embodiments of the present application. The garment steamer 100 may comprise a power source 10, a heating element 20, a temperature controller 30, a pump 40, a transistor drive circuit 50, and a switch 60. The power source 10, the pump 40, the transistor drive circuit 50, and the switch 60 can be connected in series to form a first circuit loop. The power source 10, the heating element 20, the transistor drive circuit 50, and the switch 60 can be connected in series to form a second circuit loop. The power source 10, the heating element 20, the temperature controller 30, and the switch 60 can be connected in series to form a third circuit loop. The heating element 20 can be connected in parallel with the pump 40. The temperature controller 30 can be connected in parallel with the transistor drive circuit 50. The power source 10 is arranged to provide electrical energy for the garment steamer 100. The switch 60 can control the start and stop of the garment steamer 100. The temperature controller 30 can sense the temperature of the heating element 20, so as to control the heating element 20 to work or stop working through the transistor drive circuit 50. Under the control of the temperature controller 30, the transistor drive circuit 50 is able to control the pump 40 to operate.

When the switch 60 is turned off, the first circuit loop is not energized, the second circuit loop is not energized, and the third circuit loop is not energized. Thus, the garment steamer 100 does not work.

When the switch 60 is turned on, the temperature controller 30 can be turned on when it senses that the temperature of the heating element 20 is lower than the preset temperature, so that the third circuit loop is energized. The heating element 20 can generate heat when the third circuit loop is energized. The garment steamer 100 can start working.

Furthermore, the temperature controller 30 may control the transistor drive circuit 50 so that the transistor drive circuit 50 is disconnected in the first circuit loop. Thus, the pump 40 does not work. In some embodiments, the transistor drive circuit 50 can be turned on in the second circuit loop, so that the heating element 20 may generate heat when the second circuit loop is powered on. In some embodiments, when the temperature controller 30 is turned on, the two ends of the transistor drive circuit 50 in the second circuit loop can be short-circuited, so that the second circuit loop is not powered on.

When the switch 60 is turned on, a switch element of the temperature controller 30 can be turned off when it is sensed that the temperature of the heating element 20 is greater than or equal to a preset peak temperature, so that the third circuit loop is not energized.

Then, the temperature controller 30 can control the transistor drive circuit 50 so that the transistor drive circuit 50 is activated on in the first circuit loop. Then the pump 40 starts to work. In some embodiments, the transistor drive circuit 50 can be turned on in the second circuit loop, so that the heating element 20 can generate heat when the second circuit loop is powered on. In some embodiments, the transistor drive circuit 50 can be disconnected in the second circuit loop.

It can be understood that when the pump 40 starts working, it can provide water to the area where the heating element 20 is located, so that the water is heated by the heating element 20 to generate steam, thereby further realizing the ironing function of the garment steamer 100.

Furthermore, the temperature of the heating element 20 can be lowered under the action of water, so that the temperature controller 30 can sense that the temperature of the heating element 20 which can be reduced to be lower than the preset lower threshold temperature. Then, the temperature controller 30 is switched on when sensing that the temperature of the heating element 20 is lower than the lower threshold temperature.

In addition, in some embodiments, the heat generated by the heating element 20 in the second circuit loop is less than the heat generated by the heating element 20 in the third circuit loop, and is insufficient to compensate for the heat consumed by the heating element 20 in evaporating water.

The transistor drive circuit 50 in the garment steamer 100 uses transistors that are much cheaper than high-end chips such as processors and microcontroller units, so the cost of the garment steamer 100 controlled by the temperature controller 30 and the transistor drive circuit 50 is relatively low.

In addition, when the garment steamer 100 is in use, the switch 60 can be turned on, and then the heating element 20 and the pump 40 automatically cooperate to intelligently prevent scalding and generate steam. When the garment steamer 100 is not in use, the switch 60 can be directly turned off. During the entire use process of the garment steamer 100, too much human intervention is not required, which is convenient for users and can improve the user experience.

Please refer to FIG. 1, the power source 10 can be a storage battery, AC power, etc., which can be specifically determined according to the needs of those skilled in the art and will not be described in detail.

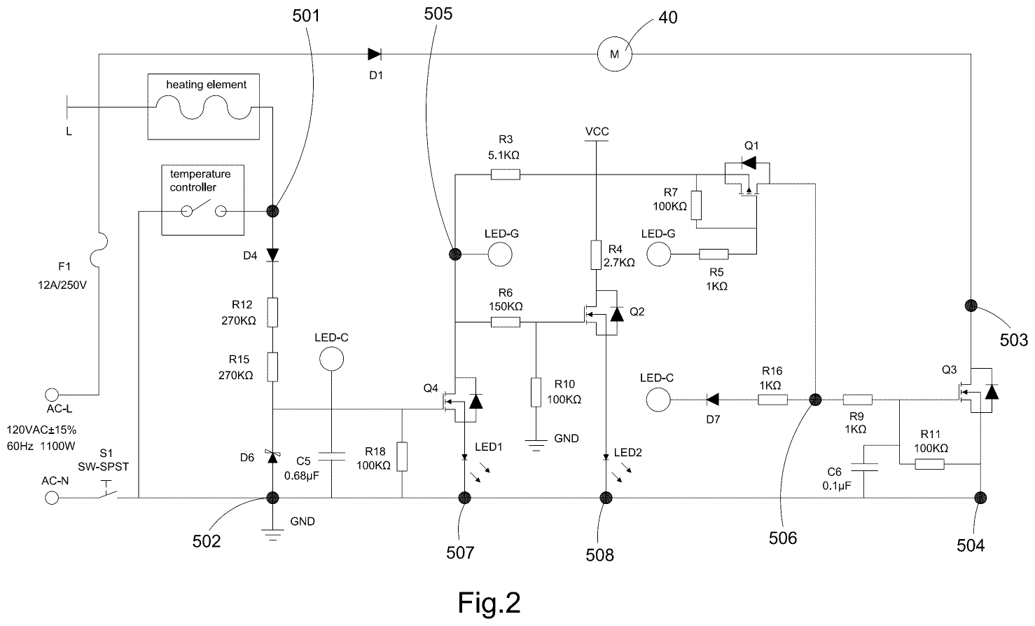

The power source 10 can be alternating current. Please refer to FIG. 2, which is a schematic diagram of the structure of the garment steamer 100 according to the embodiment shown in FIG. 1. The power source 10 can be 120V±15% alternating current. In some embodiments, the frequency of the power source 10 is 60 Hz. In some embodiments, the power of the power source 10 can be 1100 W.

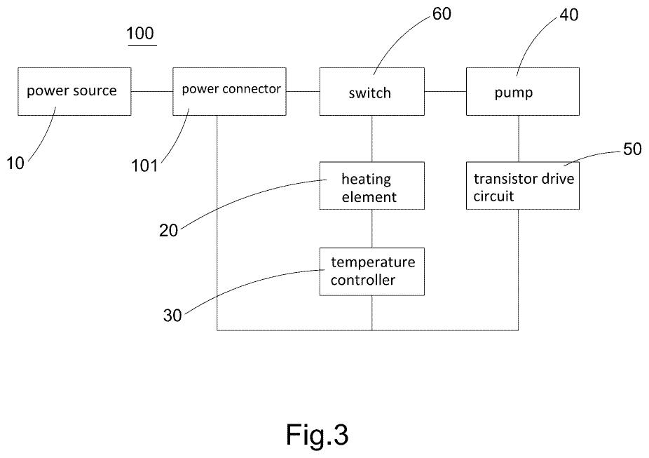

In some embodiments, the power source 10 can be built into the garment steamer 100. In some embodiments, the power source 10 can be external, and thus may not be part of the garment steamer 100, but may also be part of the garment steamer 100. Please refer to FIG. 3, which is a schematic diagram of the structure of the garment steamer 100 according to the embodiment shown in FIG. 1. The power source 10 is external, and the garment steamer 100 may comprise a power connector 101 electrically connected to the temperature controller 30, the transistor drive circuit 50, and the switch 60, respectively. The power connector 101 can be electrically connected to the power source 10. Of course, the power source 10 may also be built in. In some embodiments, the power connector 101 can be a plug, and of course it can be a structure that can realize electrical connection well known to those skilled in the art.

Referring to FIG. 1, the heating element 20 can be mainly made of a resistor, and is made by utilizing the characteristic that the resistor generates heat when current is passed through it. Furthermore, the heating element 20 can generate heat when current is passed through it. In some embodiments, the heating element 20 can be a heating wire. Of course, the heating element 20 can also select other heat-generating devices according to the needs of those skilled in the art, which will not be described in detail.

Please refer to FIG. 2, one end of the heating element 20 can be electrically connected to the live wire of the power source 10, and the other end can be electrically connected to one end of the temperature controller 30 and one end of the transistor drive circuit 50. The other end of the temperature controller 30 and the other end of the transistor drive circuit 50 can both be electrically connected to one end of the switch 60. The other end of the switch 60 can be electrically connected to the neutral wire of the power source 10.

Referring to FIG. 2, a first rectifier diode D1 can be provided on the first circuit loop formed by the power source 10, the pump 40, the transistor drive circuit 50, and the switch 60, so as to realize a unidirectional flow of current. In some embodiments, the first rectifier diode D1 can be connected in series with the pump 40 and in parallel with the heating element 20. In some embodiments, the positive electrode of the first rectifier diode D1 is electrically connected to the the live wire of the power source 10, and the negative electrode is electrically connected to the pump 40.

Referring to FIG. 2, the switch 60 can be a single-pole single-throw switch (ST-SPST) S1.

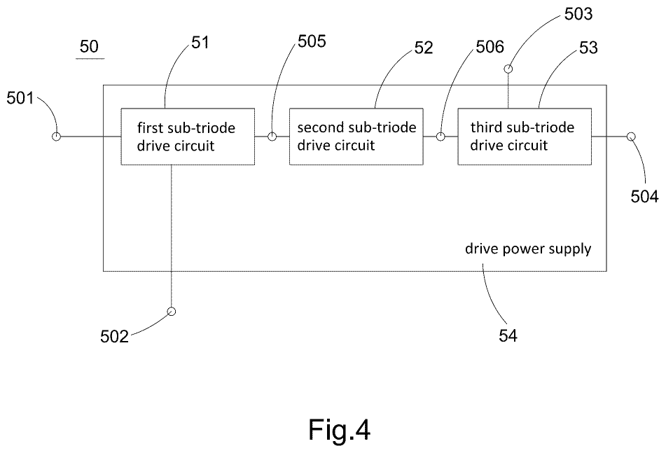

Please refer to FIG. 4, which is a schematic diagram of the structure of the transistor drive circuit 50 according to the embodiment shown in FIG. 1. The transistor drive circuit 50 may comprises a first sub-triode drive circuit 51, a second sub-triode drive circuit 52, a third sub-triode drive circuit 53 and a drive power supply 54. The first sub-triode drive circuit 51 can be connected in series with the power source 10, the heating element 20, and the switch 60 to form the second circuit loop. The third sub-triode drive circuit 53 can be connected in series with the power source 10, the pump 40, and the switch 60 to form the first circuit loop. The second sub-triode drive circuit 52 can be electrically connected to the first sub-triode drive circuit 51 and the third sub-triode drive circuit 53, so that the first sub-triode drive circuit 51 can control the second sub-triode drive circuit 52, and indirectly control the third sub-triode drive circuit 53 through the second sub-triode drive circuit 52. The drive power supply 54 is electrically connected to the first sub-transistor drive circuit 51, the second sub-transistor drive circuit 52, and the third sub-transistor drive circuit 53 respectively to provide power to the first sub-transistor drive circuit 51, the second sub-transistor drive circuit 52, and the third sub-transistor drive circuit 53.

The first sub-transistor drive circuit 51 can be electrically connected between a first terminal 501 and a second terminal 502 to be electrically connected in the second circuit loop through the first terminal 501 and the second terminal 502.

The third sub-transistor drive circuit 53 can be electrically connected between a third terminal 503 and a fourth terminal 504, so as to be electrically connected in the first circuit loop through the third terminal 503 and the fourth terminal 504.

The second sub-transistor drive circuit 52 can be electrically connected between a fifth terminal 505 and a sixth terminal 506, so as to be electrically connected to the first sub-transistor drive circuit 51 through the fifth terminal 505, and to the third sub-transistor drive circuit 53 through the sixth terminal 506.

When the second circuit loop formed by the first sub-transistor drive circuit 51, the power source 10, the heating element 20, and the switch 60 is connected in series, the first terminal 501 is at a high level. When the second circuit loop formed by the first sub-transistor drive circuit 51, the power source 10, the heating element 20, and the switch 60 is disconnected, the first terminal 501 is at a low level.

When the first terminal 501 is at the high level, the first sub-transistor drive circuit 51 outputs a low level based on the drive power supply 54 at the fifth terminal 505.

When the first terminal 501 is at the low level, the first sub-transistor drive circuit 51 outputs a high level based on the drive power supply 54 at the fifth terminal 505.

When the fifth terminal 505 of the second sub-transistor drive circuit 52 is at the high level, the sixth terminal 506 of the second sub-transistor drive circuit 52 outputs a low level based on the drive power supply 54.

When the fifth terminal 505 of the second sub-transistor drive circuit 52 is at the low level, the sixth terminal 506 of the second sub-transistor drive circuit 52 outputs a high level based on the drive power supply 54.

When the sixth terminal 506 of the third sub-transistor drive circuit 53 is at the high level, the third terminal 503 and the fourth terminal 504 are turned on, so that the first circuit loop formed by the third sub-transistor drive circuit 53 in series with the power source 10, the pump 40, and the switch 60 is turned on.

When the sixth terminal 506 of the third sub-transistor drive circuit 53 is at the low level, the third terminal 503 and the fourth terminal 504 are disconnected, so that the first circuit loop formed in series with the third sub-transistor drive circuit 53, the power source 10, the pump 40, and the switch 60 is disconnected.

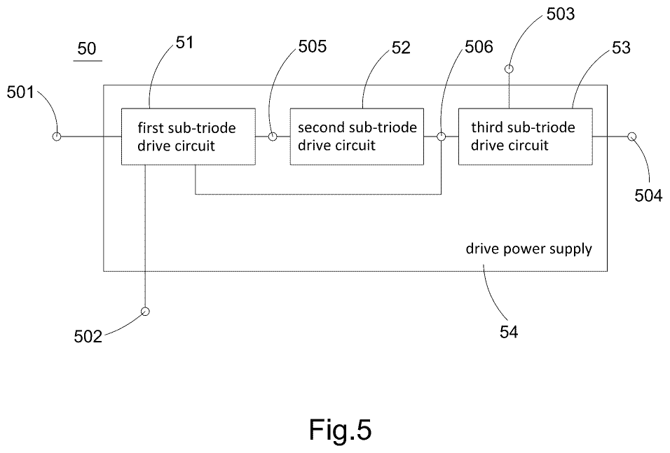

Please refer to FIG. 5, which is a schematic diagram of the structure of the transistor drive circuit 50 in the embodiment shown in FIG. 4. The first sub-transistor drive circuit 51 can be electrically connected to the sixth terminal 506, so that when the sixth terminal 506 is at the high level, the first sub-transistor drive circuit 51 outputs a low level based on the drive power supply 54 at the fifth terminal 505 to achieve a self-locking function. In some embodiments, when the first circuit loop is turned on, the first sub-transistor drive circuit 51 cooperates with the second sub-transistor drive circuit 52 to maintain the first circuit loop turned on without being affected by the temperature controller 30. For example, the sixth terminal 506 is at the high level, which will make the first circuit loop turned on, and the high level of the sixth terminal 506 is fed back to the first sub-transistor drive circuit 51, which can make the first sub-transistor drive circuit 51 maintain a low level at the fifth terminal 505, and then make the second sub-transistor drive circuit 52 maintain a high level at the sixth terminal 506, so as to achieve a self-locking function and maintain the first circuit loop turned on. Under the control of the temperature controller 30, the third circuit loop does not affect the sixth terminal 506 to maintain a high level, so that the first circuit loop remains conductive without being affected by the temperature controller 30.

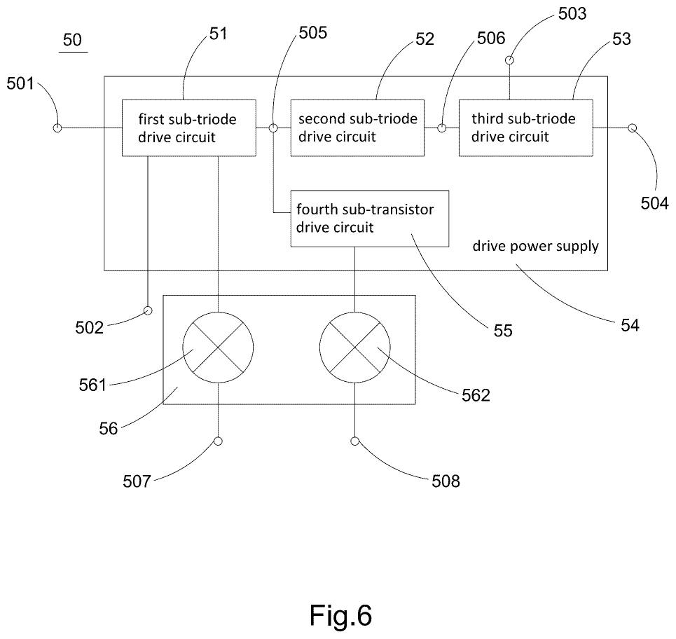

Please refer to FIG. 6, which is a schematic diagram of the structure of the transistor drive circuit 50 according to the embodiment shown in FIG. 5. The transistor drive circuit 50 may also comprise a fourth sub-transistor drive circuit 55 and an indicator light assembly 56. The first sub-transistor drive circuit 51 is connected in series with the indicator light assembly 56 and the drive power supply 54 to form a circuit loop. The fourth sub-transistor drive circuit 55 is connected in series with the indicator light assembly 56 and the drive power supply 54 to form a circuit loop.

When the first terminal 501 is at a high level, the first sub-transistor drive circuit 51 conducts the circuit loop formed by the first sub-transistor drive circuit 51, the indicator light assembly 56, and the drive power supply 54, so that the indicator light assembly 56 sends out a first indication signal. When the first terminal 501 is at the low level, the first sub-transistor drive circuit 51 disconnects the circuit loop formed by the first sub-transistor drive circuit 51, the indicator light 56, and the drive power supply 54, so that the indicator light 56 does not send out the first indication signal.

When the fifth terminal 505 of the fourth sub-transistor drive circuit 55 is at the high level, the circuit loop formed by the fourth sub-transistor drive circuit 55, the indicator light assembly 56, and the drive power supply 54 is turned on, so that the indicator light assembly 56 sends out a second indication signal. When the fifth terminal 505 of the fourth sub-transistor drive circuit 55 is at the low level, the circuit loop formed by the fourth sub-transistor drive circuit 55, the indicator light 56, and the drive power supply 54 is turned off, so that the indicator light 56 does not send out the second indication signal.

In some embodiments, the indicator light assembly 56 may comprise a first indicator light 561 and a second indicator light 562. The first indicator light 561 is used to send a first indication signal. The second indicator light 562 is used to send a second indication signal. In some embodiments, the first indication signal is a colored light. In some embodiments, the first indication signal is a green light. In some embodiments, the second indication signal is a colored light. In some embodiments, the second indication signal is a red light.

In some embodiments, the indicator light assembly 56, such as the first indicator light 561, is electrically connected to the seventh terminal 507, and then the indicator light 56, such as the first indicator light 561, is connected in series between the first sub-transistor drive circuit 51 and the seventh terminal 507, so as to realize a fourth circuit loop formed by the transistor drive circuit 50, such as the first sub-transistor drive circuit 51, the indicator light assembly 56, such as the first indicator light 561, and the drive power supply 54. In some embodiments, when the first circuit loop is turned on, the first sub-transistor drive circuit 51 maintains the fourth circuit loop disconnected and is not affected by the temperature controller 30. For example, the sixth terminal 506 is at a high level to make the first circuit loop turned on, and the high level of the sixth terminal 506 is fed back to the first sub-transistor drive circuit 51, so that the first sub-transistor drive circuit 51 maintains a low level at the fifth terminal 505, and then the second sub-transistor drive circuit 52 maintains a high level at the sixth terminal 506, so as to realize the self-locking function and maintain the first circuit loop turned on. The third circuit loop does not affect the sixth terminal 506 maintaining a high level under the control of the temperature controller 30, so that the first sub-transistor drive circuit 51 disconnects the fourth circuit loop when the sixth terminal 506 maintains a high level without being affected by the temperature controller 30.

In some embodiments, the second indicator light 562 of the indicator light assembly 56 is electrically connected to an eighth terminal 508, and then the second indicator light 562 of the indicator light assembly 56 is connected in series between the fourth sub-transistor drive circuit 55 and the eighth terminal 508, so as to realize a fifth circuit loop formed by the transistor drive circuit 50, such as the fourth sub-transistor drive circuit 55, the indicator light 56, such as the second indicator light 562, and the drive power supply 54. In some embodiments, when the first circuit loop is turned on, the first sub-transistor drive circuit 51 cooperates with the fourth sub-transistor drive circuit 55 to maintain the conduction of the fifth circuit loop without being affected by the temperature controller 30. For example, the sixth terminal 506 is at the high level, so that the first circuit loop is turned on, and the high level of the sixth terminal 506 is fed back to the first sub-transistor drive circuit 51, so that the first sub-transistor drive circuit 51 maintains a low level at the fifth terminal 505, and then the second sub-transistor drive circuit 52 maintains a high level at the sixth terminal 506, so as to realize the self-locking function and maintain the conduction of the first circuit loop. The third circuit loop does not affect the sixth terminal 506 maintaining a high level under the control of the temperature controller 30, and the fourth sub-transistor drive circuit 55 turns on the fifth circuit loop when the fifth terminal 505 maintains a low level without being affected by the temperature controller 30.

Please refer to FIG. 2, the first terminal 501 is disposed at an electrical connection position between the heating element 20 and the temperature controller 30 and the transistor drive circuit 50, such as the first sub-transistor drive circuit 51, a connection position here can be referred to as a first electrical connection position. The second terminal 502 is disposed at an electrical connection position between the temperature controller 30 and the transistor drive circuit 50, such as the first sub-transistor drive circuit 51, and the switch 60, a connection position here can be referred to as a second electrical connection position.

Referring to FIG. 2, the first sub-transistor drive circuit 51 may comprise a fourth rectifier diode D4, a twelfth resistor R12, a fifteenth resistor R15, and a sixth voltage stabilizing diode D6, which are sequentially connected in series between the first terminal 501 and the second terminal 502. The first sub-transistor drive circuit 51 may also comprise a fifth capacitor C5 connected in parallel with the sixth voltage stabilizing diode D6. The first sub-transistor drive circuit 51 may also comprise an eighteenth resistor R18 connected in parallel with the sixth voltage stabilizing diode D6. One end of the fifth capacitor C5 can be electrically connected to one end of the fifteenth resistor R15 connected to the sixth voltage stabilizing diode D6, and the other end can be electrically connected to the second terminal 502. One end of the eighteenth resistor R18 can be electrically connected to one end of the fifteenth resistor R15 connected to the sixth voltage stabilizing diode D6, and the other end can be electrically connected to the second terminal 502.

In some embodiments, a positive electrode of the fourth rectifier diode D4 is electrically connected to the first terminal 501, and a negative electrode of the fourth rectifier diode D4 is electrically connected to the twelfth resistor R12.

In some embodiments, a positive electrode of the sixth voltage zener diode D6 is electrically connected to the second end 502, and the other end is electrically connected to the fifteenth resistor R15.

In some embodiments, the resistance value of the twelfth resistor R12 is 270 KΩ.

In some embodiments, the resistance value of the fifteenth resistor R15 is 270 KΩ.

In some embodiments, the capacitance of the fifth capacitor C5 is 0.68 μF.

In some embodiments, the resistance value of the eighteenth resistor R18 is 100 KΩ.

In some embodiments, the second terminal 502 is grounded.

Referring to FIG. 2, the first sub-transistor drive circuit 51 may comprise a fourth N-channel enhancement type field effect transistor Q4. The gate of the fourth N-channel enhancement type field effect transistor Q4 can be electrically connected to one end of the fifteenth resistor R15 which is connected to the sixth voltage stabilizing diode D6. The drain of the fourth N-channel enhancement type field effect transistor Q4 can be electrically connected to the fifth end 505. The source of the fourth N-channel enhancement type field effect transistor Q4 can be electrically connected to the seventh end 507. The drain of the fourth N-channel enhancement type field effect transistor Q4 can be electrically connected to the fifth end 505. In some embodiments, the seventh end 507 is electrically connected to the second end 502 and grounded. In some embodiments, the fifth end 505 and the seventh end 507 are respectively electrically connected to the drive power supply 54, so that the fourth N-channel enhancement type field effect transistor Q4 is electrically connected to the drive power supply 54. In some embodiments, the fifth end 505 can be connected to the drive power supply 54, for example, with a third resistor R3 between the access voltage end VCC. In some embodiments, the resistance value of the third resistor R3 is 5.1 KΩ.

In some embodiments, the first indicator light 561 of the indicator light assembly 56 can be connected in series between the source of the fourth N-channel enhancement type field effect transistor Q4 and the seventh terminal 507.

Please refer to FIG. 2, the second sub-transistor drive circuit 52 may comprise a fifth resistor R5 having one end electrically connected to the fifth terminal 505 through the indicator terminal LED-G, a first P-channel enhancement type field effect transistor Q1 having a gate electrically connected to the other end of the fifth resistor R5, and a seventh resistor R7 having one end electrically connected to the gate of the first P-channel enhancement type field effect transistor Q1. The other end of the seventh resistor R7 is electrically connected to the source of the first P-channel enhancement type field effect transistor Q1 and the access voltage terminal VCC of the drive power supply 54. The source of the first P-channel enhancement type field effect transistor Q1 can be electrically connected to the sixth terminal 506. In some embodiments, the sixth terminal 506 can be connected in series with the gate of the fourth N-channel enhancement type field effect transistor Q4 to form a sixteenth resistor R16 and a seventh rectifier diode D7. In some embodiments, the resistance value of the fifth resistor R5 is 1 KΩ. In some embodiments, the resistance value of the seventh resistor R7 is 100 KΩ. In some embodiments, the resistance value of the sixteenth resistor R16 is 1 KΩ. In some embodiments, the sixth terminal 506 can be electrically connected to one end of the sixteenth resistor R16, and the other end of the sixteenth resistor R16 can be electrically connected to the positive electrode of the seventh rectifier diode D7. The positive electrode of the seventh rectifier diode D7 can be electrically connected to the gate of the fourth N-channel enhancement type field effect transistor Q4.

Referring to FIG. 2, the third sub-transistor drive circuit 53 may comprise a ninth resistor R9 having one end electrically connected to the sixth terminal 506, a third N-channel enhancement type field effect transistor Q3 having a gate electrically connected to the other end of the ninth resistor R9, and an eleventh resistor R11 having one end electrically connected to the gate of the third N-channel enhancement type field effect transistor Q3. The drain of the third N-channel enhancement type field effect transistor Q3 is electrically connected to the third terminal 503. The source of the third N-channel enhancement type field effect transistor Q3 and the other end of the eleventh resistor R11 are both electrically connected to the fourth terminal 504. In some embodiments, the fourth terminal 504 is electrically connected to the seventh terminal 507 and the second terminal 502, and is grounded. In some embodiments, the third sub-transistor drive circuit 53 may comprise a sixth capacitor C6 having one end electrically connected to the gate of the third N-channel enhancement type field effect transistor Q3 and the other end electrically connected to the fourth terminal 504. In some embodiments, the resistance value of the ninth resistor R9 is 1 KΩ. In some embodiments, the resistance value of the eleventh resistor R11 is 100 KΩ. In some embodiments, the capacitance of the sixth capacitor C6 is 0.1 μF.

Please refer to FIG. 2, the fourth sub-transistor drive circuit 55 may comprise a sixth resistor R6 electrically connected to the fifth terminal 505 at one end, a second N-channel enhancement type field effect transistor Q2 whose gate is electrically connected to the other end of the sixth resistor R6, a tenth resistor R10 electrically connected to the gate of the second N-channel enhancement type field effect transistor Q2 at one end and grounded at the other end, and a fourth resistor R4 electrically connected to the drain of the second N-channel enhancement type field effect transistor Q2 at one end and electrically connected to the drive power supply 54, such as the voltage terminal VCC at the other end. The source of the second N-channel enhancement type field effect transistor Q2 can be electrically connected to the eighth terminal 508. In some embodiments, the eighth terminal 508 is electrically connected to the fourth terminal 504, the seventh terminal 507, and the second terminal 502, and is grounded. In some embodiments, the source of the second N-channel enhancement type field effect transistor Q2 can be connected in series with the second indicator light 562 (indicator light LED2) and the eighth terminal 508. In some embodiments, the grounded end of the tenth resistor R10 can be electrically connected to the eighth terminal 508. In some embodiments, the resistance value of the sixth resistor R6 is 150 KΩ. In some embodiments, the resistance value of the tenth resistor R10 is 100 KΩ. In some embodiments, the resistance value of the fourth resistor R4 is 2.7 KΩ.

Please refer to FIG. 2, when the switch 60, such as the switch S1, is disconnected, the third circuit loop formed by the power source 10, the heating element 20, the temperature controller 30 and the switch 60, such as the switch S1, is not energized, the second circuit loop formed by the power source 10, the heating element 20, the transistor drive circuit 50, such as the first sub-transistor drive circuit 51 and the switch 60, such as the switch S1, is not energized, and the first circuit loop formed by the power source 10, the pump 40, the transistor drive circuit 50, such as the third sub-transistor drive circuit 54 and the switch 60, such as the switch S1, is not energized. Thus, the garment steamer 100 does not work.

When the switch 60, such as the switch S1, is turned on, the temperature controller 30 can be switched on when it senses that the temperature of the heating element 20 is lower than the preset temperature, so that the third circuit loop formed by the power source 10, the heating element 20, the temperature controller 30 and the switch 60, such as the switch S1, is energized. The heating element 20 may generate heat when the third circuit loop formed by the power source 10, the heating element 20, the temperature controller 30 and the switch 60, such as the switch S1, is energized. The garment steamer 100 may start to work.

Furthermore, the gate of the fourth N-channel enhancement type field effect transistor Q4 is in a low level state, the fourth N-channel enhancement type field effect transistor Q4 is not conducting, the fifth terminal 505 is in a high level state, and further the gate of the first P-channel enhancement type field effect transistor Q1 is in a high level state, the first P-channel enhancement type field effect transistor Q1 is not conducting, so that the sixth terminal 506 is in a low level state, the gate of the third N-channel enhancement type field effect transistor Q3 is in a low level state, the third N-channel enhancement type field effect transistor Q3 is not conducting, so that the transistor drive circuit 50, for example, the third sub-transistor drive circuit 53 is disconnected in the first circuit loop formed by the power source 10, the pump 40, the transistor drive circuit 50 and the switch 60. Then the pump 40 does not work.

In some embodiments, the fifth terminal 505 is in a high level state, and thus the gate of the second N-channel enhancement type field effect transistor Q2 can be in a high level state, and the second indicator light 562 (indicator light LED2) emits light. The gate of the fourth N-channel enhancement type field effect transistor Q4 is in a low level state, the fourth N-channel enhancement type field effect transistor Q4 is not turned on, and the the first indicator light 561 (indicator light LED1) does not emit light.

In some embodiments, the transistor drive circuit 50, such as the first sub-transistor drive circuit 51, can be turned on in the second circuit loop formed by the power source 10, the heating element 20, the transistor drive circuit 50 and the switch 60 through the fourth rectifier diode D4, the twelfth resistor R12, the fifteenth resistor R15, the sixth voltage regulator diode D6, the fifth capacitor C5, and the eighteenth resistor R18, so that the heating element 20 can generate heat when the second circuit loop formed by the power source 10, the heating element 20, the transistor drive circuit 50 and the switch 60 is energized. In some embodiments, when the temperature controller 30 is switched on, the first terminal 501 and the second end 502 can be short-circuited, so that the second circuit loop formed by the power source 10, the heating element 20, the transistor drive circuit 50 and the switch 60 is not energized.

When the switch 60 is turned on, the temperature controller 30 can be turned off when it has sensed that the temperature of the heating element 20 is greater than or equal to a preset peak temperature, so that the third circuit loop is not energized.

Then, the gate of the fourth N-channel enhancement type field effect transistor Q4 is in a high level state, the fourth N-channel enhancement type field effect transistor Q4 is turned on, the fifth terminal 505 is in a low level state, and then the gate of the first P-channel enhancement type field effect transistor Q1 is in a low level state, the first P-channel enhancement type field effect transistor Q1 is turned on, so that the sixth terminal 506 is in a high level state, the gate of the third N-channel enhancement type field effect transistor Q3 is in a high level state, the third N-channel enhancement type field effect transistor Q3 is turned on, so that the transistor drive circuit 50, such as the third sub-transistor drive circuit 53, is turned on in the first circuit loop formed by the power source 10, the pump 40, the transistor drive circuit 50 and the switch 60. Then the pump 40 starts to operate.

In some embodiments, the fifth terminal 505 is in a low level state, and thus the gate of the second N-channel enhancement type field effect transistor Q2 can be in a low level state, and the second indicator light 562 (indicator light LED2), does not emit light. The gate of the fourth N-channel enhancement type field effect transistor Q4 is in a high level state, the fourth N-channel enhancement type field effect transistor Q4 is turned on, and the first indicator light 561 (indicator light LED1) emits light.

In some embodiments, the sixth terminal 506 is in a high level state, so that the gate of the fourth N-channel enhancement type field effect transistor Q4 is in a high level state to form an interlock, so that the gate of the fourth N-channel enhancement type field effect transistor Q4 is permanently in a high level state when the switch 60, such as the switch S1, is turned on, and the first indicator light 561 (indicator light LED1) emits light, and the second indicator light 562 (indicator light LED2) does not emit light. When the switch 60, such as the switch S1, is turned off, the first indicator light 561 (indicator light LED1) does not emit light, and the second indicator light 562 (indicator light LED2) does not emit light.

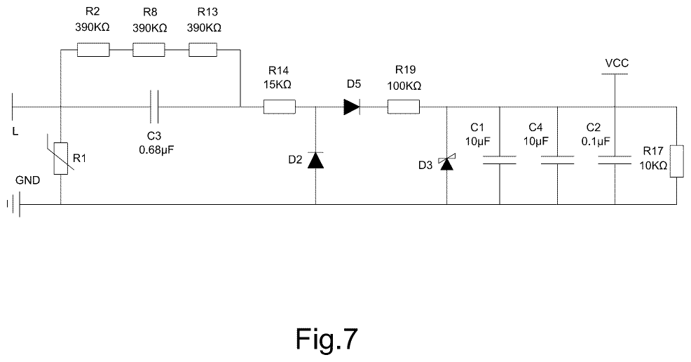

The drive power supply 54 can be electrically connected to the power source 10 so that the power source 10 provides power for the transistor drive circuit 50. Of course, the drive power supply 54 can be electrically connected to the power source 10 through the power connector 101. Please refer to FIG. 7, which is a circuit diagram of the drive power supply 54 according to the embodiment shown in FIG. 4. The drive power supply 54 may comprise a second resistor R2, an eighth resistor R8, a thirteenth resistor R13, a fourteenth resistor R14, a fifth rectifier diode D5 and a nineteenth resistor R19, which are sequentially connected between the power source 10, such as the live wire, and the access voltage terminal VCC. In some embodiments, the fifth rectifier diode D5 can be connected in series between the fourteenth resistor R14 and the nineteenth resistor R19, so that the positive electrode of the fifth rectifier diode D5 can be electrically connected to one end of the fourteenth resistor R14, the negative electrode is electrically connected to one end of the nineteenth resistor R19, and the other end of the nineteenth resistor R19 is electrically connected to the access voltage terminal VCC. In some embodiments, the drive power supply 54 may also comprise a third capacitor C3. One end of the third capacitor C3 is electrically connected to the live wire of the power source 10, and the other end is electrically connected to the other end of the fourteenth resistor R14. The second resistor R2, the eighth resistor R8 and the thirteenth resistor R13 are connected in series in sequence and then connected in parallel with the third capacitor C3. In some embodiments, the drive power supply 54 may also comprise a third voltage stabilizing diode D3, a first capacitor C1, a fourth capacitor C4, a second capacitor C2, and a seventeenth resistor R17 electrically connected between the access voltage terminal VCC and the ground and connected in parallel with each other. In some embodiments, the positive electrode of the third voltage stabilizing diode D3 is electrically connected to the ground, and the negative electrode is electrically connected to the access voltage terminal VCC. In some embodiments, the drive power supply 54 also comprises a first varistor R1 electrically connected between the the live wire of the power source 10 and the ground.

In some embodiments, the resistance value of the second resistor R2 is 390 KΩ. In some embodiments, the resistance value of the eighth resistor R8 is 390 KΩ. In some embodiments, the resistance value of the thirteenth resistor R13 is 390 KΩ. In some embodiments, the resistance value of the fourteenth resistor R14 is 15 KΩ. In some embodiments, the resistance value of the seventeenth resistor R17 is 10 KΩ. In some embodiments, the resistance value of the nineteenth resistor R19 is 100 KΩ. In some embodiments, the resistance value of the first capacitor C1 is 10 μF. In some embodiments, the resistance value of the second capacitor C2 is 0.1 μF. In some embodiments, the resistance value of the third capacitor C3 is 0.68 μF. In some embodiments, the resistance value of the fourth capacitor C4 is 10 μF.

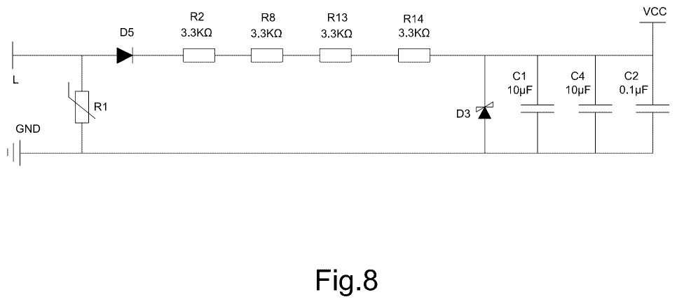

Please refer to FIG. 8, which is a circuit diagram of an alternative drive power supply 54 according to the embodiment shown in FIG. 4. The seventeenth resistor R17 in FIG. 7 can be omitted. The nineteenth resistor R19 can be omitted. The third capacitor C3 can be omitted. In some embodiments, the resistance value of the second resistor R2 is 3.3 KΩ. In some embodiments, the resistance value of the eighth resistor R8 is 3.3 KΩ. In some embodiments, the resistance value of the thirteenth resistor R13 is 3.3 KΩ. In some embodiments, the resistance value of the fourteenth resistor R14 is 3.3 KΩ.

It is understandable that the drive power supply 54 can also be configured using a technical solution well known to those skilled in the art, which will not be elaborated herein.

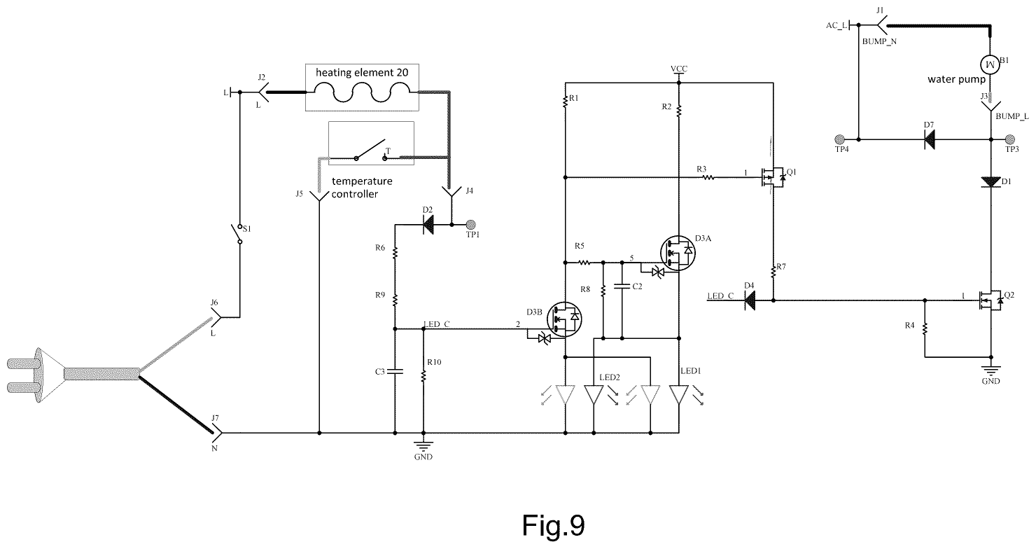

Referring to FIG. 9, an alternative garment steamer according to another embodiment is illustrated. Differed from the embodiment shown in FIG. 2 in the third sub-transistor drive circuit 53, the sixth capacitor C6, which has one end electrically connected to the gate of the third N-channel enhancement type field effect transistor Q3 and the other end electrically connected to the fourth terminal 504, can be omitted to reduce the cost.

In addition, it is worth mentioning that after the power switch 60 is turned off, the first indicator light 561 which is the green light is turned off, but the energy in the power supply has not been fully discharged yet. Once the LED is off, the excess charge accumulates between R5 and R1, which may temporarily exceed the gate threshold voltage Vgs(th) of the N-MOS transistor, causing the excess energy to pass through the second indicator light 562 which is the red LED. However, since the remaining charge is not significant, the red LED only flashes briefly. In this embodiment, the drive power supply 54 comprises a C2 which is connected in parallel with the eighth resistor R8. After adding the capacitor C2, the capacitor C2 is able to absorb some of the excess energy, ensuring that the remaining charge doesn't exceed the gate threshold voltage Vgs(th) of the N-MOS transistor. As a result, the red LED no longer flashes after the garment steamer is powered off.

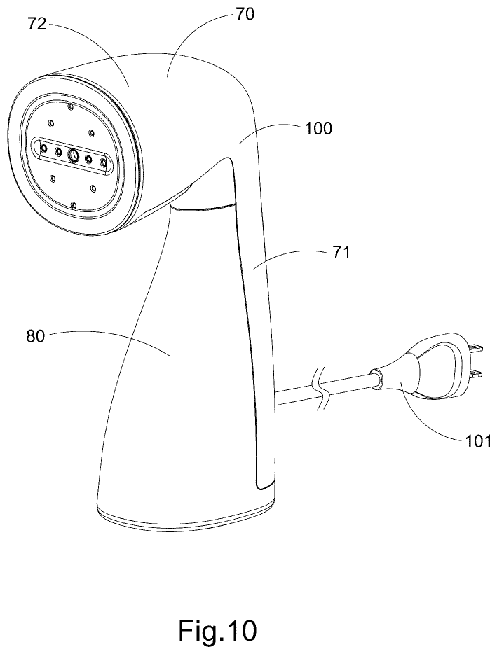

Referring to FIGS. 9 and 10 of the drawings, the garment steamer 100 comprises a housing 70 and a water tank 80, the power source 10, the heating element 20, the temperature controller 30, the pump 40, the transistor drive circuit 50 and the switch 60 are mounted to the housing 70, the water tank 80 is detachably connected to the housing 70, so as to be communicated to the pump 40, so as to supply water to the heating element 20 when the pump 40 is in operation.

In this embodiment, a side housing portion 71 is mounted to a side of the water tank 80 in a side-to-side manner, so that the water tan 80 and the side housing portion 71 form a handle part under a transverse head housing portion 72 for a user to hold thereon, so as to increase the water storing capacity of the water tank 80.

In this embodiment, the switch 60 is shifted only between an idle state and an operation state. In the idle state, the switch 60 is turned off, and in the operate state, the switch 60 is turned on, and then the garment steamer 100 automatically control the following the heating operation of the heating element 20 and the water pumping operation of the pump 40.

The heating element 20 in this embodiment is set with a preset high threshold of 160° C. and a preset low threshold of 150° C., the temperature controller 30 comprises a temperature detector which is attached to the heating element 20 in a manner that the heating operation of the heating element 20 is controlled to maintain the temperature of the heating element 20 be in the range of 150° C. to 160° C.

When the switch 60 is switched on, the heating element 20 is in a preheating state, and the second indicator light 562 which is a red indicator light is turned on to emit red light, when the heating element 20 is heated to the preset high threshold of 160° C., the heating operation of the heating element 20 is stopped, the second indicator light 562 is turned on and the first indicator light 561 which is a green indicator light is turned on to emit green light, and the pump 40 is then activated to pump water in the water tank 80 to the heating element 20 to produce steam.

When the temperature of the heating element 20 which is detected by the temperature detector of the temperature controller 30 reaches to the preset low threshold of 150° C., the heating element 20 is activated again until the heating element 20 is heated to the preset high threshold of 160° C. During this period, the second indicator light 562 will not be turned to emit red light, the first indicator light 561 is kept to be turned on to emit green light.

Accordingly, when the sixth terminal 506 is in the high-level state, this means that it provides a high voltage signal, which influences the operation of the components connected to it, particularly the gate of the fourth N-channel enhancement-type field-effect transistor Q4. The Gate of Q4 can be in a high-level state due to the high-level signal at terminal 506, the gate of the fourth N-channel enhancement-type FET (Q4) is also in the high-level state. In an N-channel enhancement-type FET, applying a high-level voltage to the gate allows the transistor to conduct, which means it will allow current to flow through its drain and source terminals, thereby turning on the circuit that Q4 controls.

The high-level state at the gate of Q4 creates an interlock condition. This interlock ensures that once the gate of Q4 is activated (high), it remains in this state as long as the switch 60 remains turned on. The permanent high-level state at gate of Q4 gate ensures stable operation without fluctuating states, leading to consistent behavior in the circuit.

When the switch (S1) is turned on, the interlock at the gate of Q4 ensures that the circuit remains in this stable state, which triggers the first indicator light 561 (LED1) to emit green light. This indicates that the system is operating correctly in its current mode.

The second indicator light 562 (LED2) does not emit light in this state, indicating that the device is no longer in the preheating phase or any other secondary mode where LED2 might be used.

The interlock created by maintaining a high-level state at the gate of Q4 ensures that the system operates in a predictable and stable manner once the switch 60 is turned on. This prevents the circuit from unintended fluctuations, contributing to smoother and more reliable device operation.

This design ensures that only the necessary indicator light is on at any given time, preventing confusion for the user. In this case, the first indicator light 561 (LED1) remains lit to confirm the garment steamer is in normal operation, while the second indicator light 562 (LED2) is off, indicating that the system is not in any preparatory or secondary mode (such as preheating). This separation of indicator lights makes it easier for the user to understand the steamer status.

In the several embodiments provided in this application, it should be understood that the disclosed device can be implemented in other ways. For example, the device implementation described above is only illustrative, for example, the division of modules or units is only a logical function division, and there can be other division methods in actual implementation, such as multiple units or components can be combined or integrated into another system, or some features can be ignored or not executed.

The units described as separate components may or may not be physically separated, and the components shown as units may or may not be physical units, that is, they can be located in one place or distributed on multiple network units. Some or all of the units can be selected according to actual needs to achieve the purpose of the present embodiment.

In addition, each functional unit in each embodiment of the present application can be integrated into one processing unit, or each unit may exist physically separately, or two or more units can be integrated into one unit. The above integrated unit can be implemented in the form of hardware or in the form of software functional units.

The above description is only an embodiment of the present application, and does not limit the patent scope of the present application. Any equivalent structure or equivalent process transformation made by using the contents of the present application specification and drawings, or directly or indirectly applied in other related technical fields, is also included in the patent protection scope of the present application.

What is claimed is:

1. A garment steamer, comprising:
a power connector;
a heating element;
a temperature controller;
a pump;
a transistor drive circuit; and
a switch, wherein the power connector is used to be electrically connected to a power source, the switch is used to control start and stop of the garment steamer, the heating element is connected in parallel with the pump, the temperature controller is connected in parallel with the transistor drive circuit, the temperature controller is used to sense a temperature of the heating element and is switched on or off according to the sensed temperature;
wherein when the power connector is electrically connected to the power source, the power source, the pump, the transistor drive circuit and the switch are capable of being connected in series to form a first circuit loop, wherein the power source, the heating element, the transistor drive circuit and the switch are capable of being connected in series to form a second circuit loop, and the power source, the heating element, the temperature controller and the switch are capable of being connected in series to form a third circuit loop;
wherein the transistor drive circuit is used to connect the first circuit loop when the temperature controller is switched off, and to disconnect the first circuit loop when the temperature controller is switched on.

2. The garment steamer according to claim 1, wherein when the temperature controller is disconnected, the second circuit loop is connected, and when the temperature controller is connected, the second circuit loop is disconnected.

3. The garment steamer according to claim 1, wherein the transistor drive circuit comprises a first sub-transistor drive circuit, a second sub-transistor drive circuit and a third sub-transistor drive circuit, the first sub-transistor drive circuit is connected in series with the power source, the heating element and the switch to form the second circuit loop, the third sub-transistor drive circuit is connected in series with the power source, the pump and the switch to form the first circuit loop, and the second sub-transistor drive circuit is electrically connected to the first sub-transistor drive circuit and the third sub-transistor drive circuit;
wherein when the temperature controller is switched on, the first sub-transistor drive circuit controls the second sub-transistor drive circuit to control the third sub-transistor drive circuit to disconnect the first circuit loop;
wherein when the temperature controller is disconnected, the first sub-transistor drive circuit controls the second sub-transistor drive circuit to control the third sub-transistor drive circuit to connect the first circuit loop.

4. The garment steamer according to claim 3, wherein one end of the second sub-transistor drive circuit electrically connected to the third sub-transistor drive circuit is electrically connected to the first sub-transistor drive circuit; wherein when the first circuit loop is connected, the first sub-transistor drive circuit cooperates with the second sub-transistor drive circuit to maintain the first circuit loop to be connected.

5. The garment steamer according to claim 3, wherein the transistor drive circuit further comprises a fourth sub-transistor drive circuit, a drive power supply, a first indicator light and a second indicator light, and the drive power supply is electrically connected to the first sub-transistor drive circuit, the second sub-transistor drive circuit, the third sub-transistor drive circuit and the fourth sub-transistor drive circuit;
wherein the first sub-transistor drive circuit is capable of being connected in series with the first indicator light and the driving power source to form a fourth circuit loop, and the fourth sub-transistor drive circuit is capable of being connected in series with the second indicator light and the driving power source to form a fifth circuit loop;
wherein when the temperature controller is switched on, the first sub-transistor drive circuit is used to connect the fourth circuit loop, and the fourth sub-transistor drive circuit is used to disconnect the fifth circuit loop;
wherein when the temperature controller is switched off, the first sub-transistor drive circuit is used to disconnect the fourth circuit loop, and the fourth sub-transistor drive circuit is used to connect the fifth circuit loop.

6. The garment steamer according to claim 5, wherein one end of the second sub-transistor drive circuit electrically connected to the third sub-transistor drive circuit is electrically connected to the first sub-transistor drive circuit; wherein when the first circuit loop is connected, the first sub-transistor drive circuit keeps the fourth circuit loop be disconnected, and the first sub-transistor drive circuit cooperates with the fourth sub-transistor drive circuit to keep the fifth circuit loop be disconnected.

7. The garment steamer according to claim 4, wherein the transistor driving circuit further comprises a drive power supply which is electrically connected to the first sub-transistor drive circuit, the second sub-transistor drive circuit, and the third sub-transistor drive circuit respectively; the first sub-transistor drive circuit is electrically connected to a first electrical connection position between the heating element, the temperature controller, and the first sub-transistor drive circuit, and is electrically connected to a second electrical connection position between the temperature controller, the first sub-transistor drive circuit and the switch, so as to be connected in series with the power source, the heating element, and the switch to form the second circuit loop.

8. The garment steamer according to claim 7, wherein the first sub-transistor drive circuit comprises a fourth rectifier diode, a twelfth resistor, a fifteenth resistor and a sixth voltage-stabilizing diode connected in series in sequence, and the first sub-transistor drive circuit comprises a fifth capacitor and an eighteenth resistor respectively connected in parallel with the sixth voltage-stabilizing diode, one end of the fifth capacitor is electrically connected to an end of the fifteenth resistor which is connected to the sixth voltage-stabilizing diode, and the other end of the fifth capacitor is electrically connected to the second electrical connection position, one end of the eighteenth resistor is electrically connected to the end of the fifteenth resistor which is connected to the sixth voltage-stabilizing diode, and the other end of the eighteenth resistor is electrically connected to the second electrical connection position, a positive electrode of the fourth rectifier diode is electrically connected to the first electrical connection position, and a negative electrode is electrically connected to the twelfth resistor, a positive electrode of the sixth voltage-stabilizing diode is electrically connected to the second electrical connection position, and the other end of the sixth voltage-stabilizing diode is electrically connected to the fifteenth resistor, wherein the first sub-transistor drive circuit further comprises a fourth N-channel enhancement type field effect transistor, a gate of the fourth N-channel enhancement type field effect transistor is electrically connected to the end of fifteenth resistor which is connected to the sixth voltage-stabilizing diode connected to the, a source of the fourth N-channel enhancement type field effect transistor is electrically connected to the second electrical connection position, a drain of the fourth N-channel enhancement type field effect transistor and the second electrical connection position position are respectively electrically connected to the drive power supply, and a third resistor is connected between the drain of the fourth N-channel enhancement type field effect transistor and an access voltage terminal of the drive power supply.

9. The garment steamer according to claim 8, wherein the second sub-transistor drive circuit comprises a fifth resistor having one end electrically connected to the drain of the fourth N-channel enhancement type field effect transistor through an indicator light end, a first P-channel enhancement type field effect transistor having a gate electrically connected to the other end of the fifth resistor, and a seventh resistor having one end electrically connected to the gate of the first P-channel enhancement type field effect transistor, the other end of the seventh resistor is electrically connected to a source of the first P-channel enhancement type field effect transistor and the access voltage end of the drive power supply, a sixteenth resistor and a seventh rectifier diode are connected in series between a source of the first P-channel enhancement type field effect transistor and the gate of the fourth N-channel enhancement type field effect transistor, the source of the first P-channel enhancement type field effect transistor is electrically connected to one end of the sixteenth resistor, the other end of the sixteenth resistor is electrically connected to a positive electrode of the seventh rectifier diode, and a positive electrode of the seventh rectifier diode is electrically connected to the gate of the fourth N-channel enhancement type field effect transistor.

10. The garment steamer according to claim 9, wherein the third sub-transistor drive circuit comprises a ninth resistor having one end electrically connected to the source of the first P-channel enhancement type field effect transistor, a third N-channel enhancement type field effect transistor having a gate electrically connected to the other end of the ninth resistor, and an eleventh resistor having one end electrically connected to the gate of the third N-channel enhancement type field effect transistor, the third N-channel enhancement type field effect transistor is connected in series with the power source, the pump, and the switch to form the first circuit loop, a source of the third N-channel enhancement type field effect transistor and the other end of the eleventh resistor are both electrically connected to the second electrical connection position.

11. The garment steamer according to claim 9, further comprising a first terminal, a second terminal, a third terminal, a fourth terminal, a fifth terminal, and a sixth terminal, wherein the first sub-transistor drive circuit is capable of being electrically connected between the first terminal and the second terminal, so as to be electrically connected in the second circuit loop through the first terminal and the second terminal, wherein the third sub-transistor drive circuit is capable of being electrically connected between the third terminal and the fourth terminal, so as to be electrically connected in the first circuit loop through the third terminal and the fourth terminal, wherein the second sub-transistor drive circuit is capable of being electrically connected between the fifth terminal and the sixth terminal, so as to be electrically connected to the first sub-transistor drive circuit through the fifth terminal, and to the third sub-transistor drive circuit through the sixth terminal.

12. The garment steamer according to claim 11, wherein when the second circuit loop formed by the first sub-transistor drive circuit, the power source, the heating element, and the switch is connected in series, the first terminal is at a high level, wherein when the second circuit loop formed by the first sub-transistor drive circuit, the power source, the heating element, and the switch is disconnected, the first terminal is at a low level.

13. The garment steamer according to claim 12, wherein when the first terminal is at the high level, the first sub-transistor drive circuit outputs a low level based on the drive power supply at the fifth terminal; wherein when the first terminal is at the low level, the first sub-transistor drive circuit outputs a high level based on the drive power supply at the fifth terminal; wherein when the fifth terminal of the second sub-transistor drive circuit is at a high level, the sixth terminal of the second sub-transistor drive circuit outputs a low level based on the drive power supply; wherein when the fifth terminal of the second sub-transistor drive circuit is at a low level, the sixth terminal 506 of the second sub-transistor drive circuit outputs a high level based on the drive power supply; wherein when the sixth terminal of the third sub-transistor drive circuit is at a high level, the third terminal and the fourth terminal are turned on, and the first circuit loop formed by the third sub-transistor drive circuit in series with the power source, the pump, and the switch is connected; wherein when the sixth terminal of the third sub-transistor drive circuit is at a low level, the third terminal and the fourth terminal are disconnected, and first circuit loop is disconnected.

14. The garment steamer according to claim 11, wherein the first sub-transistor drive circuit is capable of being electrically connected to the sixth terminal, so that when the sixth terminal is at a high level, the first sub-transistor drive circuit outputs a low level based on the drive power supply at the fifth terminal to achieve a self-locking function, wherein when the first circuit loop is connected, the first sub-transistor drive circuit cooperates with the second sub-transistor drive circuit to maintain the first circuit loop to be connected without being affected by the temperature controller.

15. The garment steamer according to claim 14, wherein when the sixth terminal is at the high level, the first circuit loop is connected, the first sub-transistor drive circuit maintains a low level at the fifth terminal, and the second sub-transistor drive circuit maintain a high level at the sixth terminal, so as to achieve the self-locking function and maintain the first circuit loop to be connected.

16. The garment steamer according to claim 1, further comprising a first indicator light and a second indicator light, wherein the heating element is set with a preset high threshold and a preset low threshold, wherein when the switch is switched on, the heating element is in a preheating state, and the second indicator light is turned on, when the heating element is heated to the preset high threshold, the heating operation of the heating element is stopped, the second indicator light is turned off and the first indicator light is turned on, and the pump is then activated.

17. The garment steamer according to claim 16, wherein when the temperature of the heating element is reduced to the preset low threshold, the heating element is activated again until the heating element is heated to the preset high threshold, during this period, the second indicator light is not turned on while the first indicator light is kept to be turned on.

18. The garment steamer according to claim 11, wherein when the sixth terminal is in a high level, the gate of the fourth N-channel enhancement-type field-effect transistor is in a high level state which creates an interlock condition which ensures that once the gate of fourth N-channel enhancement-type field-effect transistor is activated, the high level state of the fourth N-channel enhancement-type field-effect transistor remains as long as the switch remains turned on.

19. The garment steamer according to claim 18, further comprising a first indicator light and a second indicator light, wherein the heating element is set with a preset high threshold and a preset low threshold, wherein when the switch is switched on, the heating element is in a preheating state, and the second indicator light is turned on, when the heating element is heated to the preset high threshold, the heating operation of the heating element is stopped, the second indicator light is turned on and the first indicator light is turned on, and the pump is then activated, and the gate of the fourth N-channel enhancement-type field-effect transistor is in the high level state and the first indicator light is kept to be turned on while the second indicator light will not be turned on again.

20. The garment steamer according to claim 1, further comprising a housing and a water tank, wherein said housing comprises a side housing portion and a head housing portion transversely extended from the side housing potion, wherein the side housing portion is detachably mounted to the water tank is a side-to-side manner to allow the water tan and the side housing portion to form a handle part under the head housing portion for a user to hold thereon.

21. The garment steamer according to claim 16, further comprising a capacitor for absorb excess energy in a manner that when the garment steamer is turned off, said first indicator light is turned off while said second indicator light does not flash.
